(19) United States
(12) Patent Application Publication
(10) Pub. No.: US 2023/0307216 A1
(43) Pub. Date: Sep. 28, 2023

(54) ENHANCED CHAMBER CLEAN AND RECOVERY WITH DUAL FLOW PATH

(71) Applicant: Applied Materials, Inc., Santa Clara, CA (US)

(72) Inventors: Prasanth Narayanan, Santa Clara, CA (US); Shrihari Sampathkumar, Mountain View, CA (US); Keiichi Tanaka, San Jose, CA (US); Mario D. Sanchez, San Jose, CA (US); Muhammad M. Rasheed, San Jose, CA (US); Mandyam Sriram, San Jose, CA (US)

(73) Assignee: Applied Materials, Inc., Santa Clara, CA (US)

(21) Appl. No.: 17/968,454

(22) Filed: Oct. 18, 2022

Related U.S. Application Data
(60) Provisional application No. 63/323,768, filed on Mar. 25, 2022.

(51) Int. Cl. H01J 37/32

(52) U.S. Cl. CPC H01J 37/32862; H01J 37/32357; H01J 37/32449; H01J 2237/327

(57) ABSTRACT

Processing chambers comprising a chamber body, a remote plasma source (RPS) outside the chamber body, a first connection line between the remote plasma source and the interior volume of the chamber body through the top wall and a second connection line between the remote plasma source and the interior volume through the sidewall of the chamber body. Methods of cleaning a processing chamber comprising flowing an etchant gas through the RPS into the chamber body, followed by a flow recovery gas through the RPS into the chamber body through both the first connection line and second connection line.

### CROSS-REFERENCE TO RELATED APPLICATIONS

This application claims priority to U.S. Provisional Application No. 63/323,768, filed Mar. 25, 2022, the entire disclosure of which is hereby incorporated by reference herein.

### TECHNICAL FIELD

Embodiments of the disclosure generally relate to apparatus and methods for cleaning a processing chamber. In particular, embodiments of the disclosure relate to apparatus and methods for processing chamber cleaning using a recovery gas flowed by dual flow paths.

### BACKGROUND

Current chamber cleaning procedures result in chamber downtime and loss of throughput. Some cleaning procedures require long clean times which can be damaging to the internal chamber parts due to exposure to reactive chemical species. These long exposure times also require increased time to recover the chamber for further processing and production.

The current state of the art cleaning process for some process chambers is to use the clean gas (NF₃) from the top of the chamber. To allow for the entire chamber to be cleaned including the backside of the heater, the clean time is increased to allow sufficient fluorine radicals to reach the chamber bottom (e.g., region under the heater).

Accordingly, there is a need in the art for apparatus and methods to improve chamber cleaning.

### SUMMARY OF THE CLAIMS

One or more embodiments of the disclosure are directed to processing chambers comprising a chamber body having a top wall, a sidewall and a bottom wall defining an interior volume. A remote plasma source (RPS) is outside the chamber body. A first connection line is between the remote plasma source (RPS) and the interior volume through the top wall. A second connection line is between the remote plasma source (RPS) and the interior volume through the sidewall.

Additional embodiments of the disclosure are directed to methods of cleaning a processing chamber. The methods comprise flowing a recovery gas into a remote plasma source (RPS) positioned outside a chamber body comprising a top wall, a sidewall and a bottom wall defining an interior volume. The recovery gas is flowed through a second connection line from the RPS to the interior volume through the sidewall of the chamber body. The recovery gas is flowed through a first connection line from the RPS to the interior volume through the top wall of the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process chamber according to one or more embodiments of the disclosure;

FIG. 2 illustrates a schematic representation process chamber according to one or more embodiments of the disclosure;

FIG. 3 illustrates a schematic representation of a portion of a second connection line in accordance with one or more embodiments of the disclosure;

FIG. 4 illustrates a second connection line in accordance with one or more embodiment of the disclosure; and

FIG. 5 shows a flowchart of a cleaning method according to one or more embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

Embodiments of the disclosure enhance chamber clean by dividing the clean gas into two lines connected to chamber top and bottom. Thus, the clean gas is introduced from the top and bottom individually. This targets the clean region and reduces overall clean time and damage to the parts. Some embodiments incorporate ammonia as a cleaning agent to recover the chamber faster after a clean.

Some embodiments of the disclosure incorporate hardware changes to reduce the clean and recovery times. Some embodiments of the disclosure reduce the recovery time by using ammonia to recover the process chamber.

Some embodiments of the disclosure introduce a gas line tied to an ammonia trifluoride (NF₃) line from the top of the process chamber. In some embodiments, the flow of fluorine radicals target the top and bottom of the chamber individually.

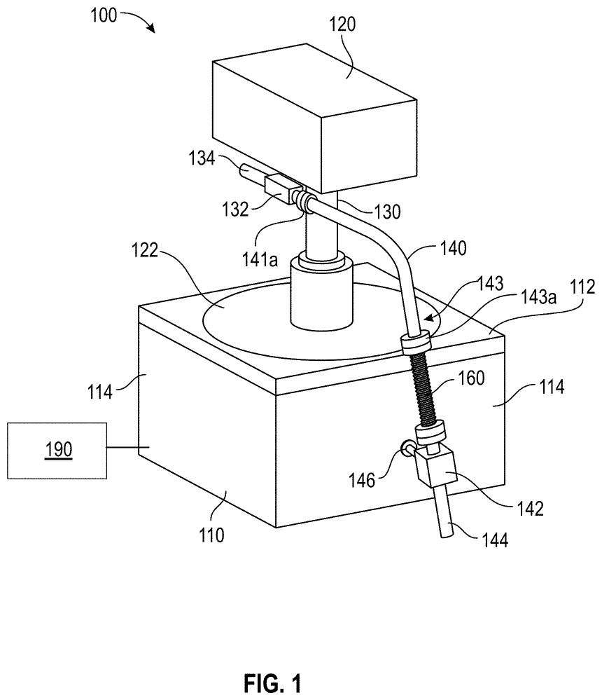

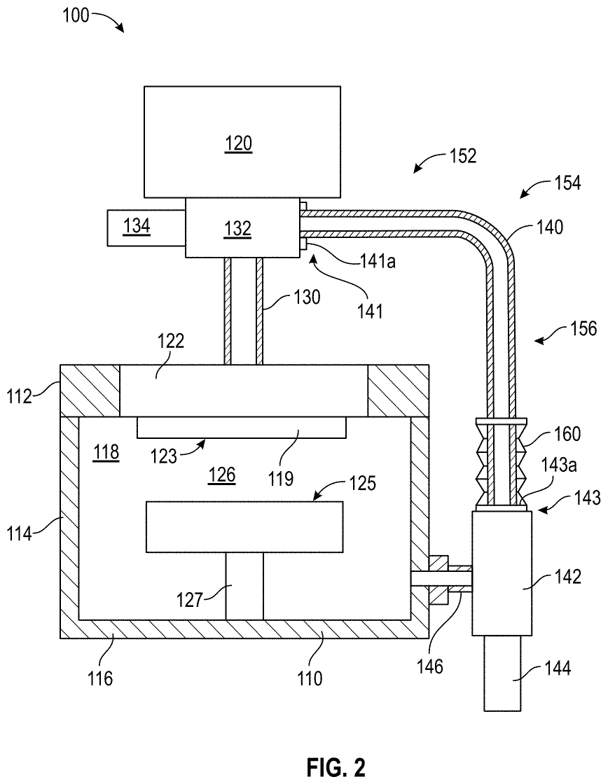

Accordingly, with reference to FIGS. 1 and 2, one or more embodiments of the disclosure are directed to processing chambers 100. The processing chamber 100 includes a chamber body 110 with a top wall 112, a sidewall 114 and a bottom wall 116 defining an interior volume 118 of the chamber. The embodiment illustrated in the Figures shows a four-sided chamber body 110. However, the skilled artisan will recognize that the chamber body 110 can have a cylindrical shape with a continuous sidewall 114 that extends around the interior volume 118.

A remote plasma source (RPS) 120 is located outside the chamber body 110. The skilled artisan will be familiar with remote plasma sources and understands that the remote plasma source can generate a plasma in a region remotely located from the interior volume 118 of the chamber body 110.

In some embodiments, the processing chamber 100 includes a showerhead 119 (or other suitable gas distribution apparatus known to the skilled artisan) and a substrate support 124 with a support surface 125 within the interior volume 118 adjacent the top wall 112. The support surface 125 of the substrate support 124 is spaced a distance from the front face 123 of the showerhead 119 creating a process gap 126. In the illustrated embodiments, the showerhead 119 is connected to a backing plate 122 that is inset into the top wall 112 of the chamber body 110. In some embodiments, the substrate support 124 is positioned on top of a support shaft 127 that is configured to rotate and/or elevate the substrate support 124 within the interior volume 118.

The plasma generated in the remote plasma source (RPS) 120 can flow into the interior volume 118 of the chamber body 110 through a suitable connection line. In some embodiments, a first connection line 130 connects the remote plasma source (RPS) 120 with the interior volume 118 of the chamber body 110 through the showerhead 119 on the top wall 112.

The first connection line 130 of some embodiments includes a first valve 132 to isolate the remote plasma source (RPS) 120 from the first connection line 132. The first valve 132 can be any suitable valve known to the skilled artisan. In some embodiments, the first valve 132 comprises a manual valve, a pneumatic valve, a solenoid valve, or a hydraulic valve. The illustrated embodiments show a pneumatic first valve 132 with a motor 134 connected to, and configured to, operate the first valve 132.

In some embodiments, as shown in the Figures, the remote plasma source (RPS) 120 is positioned above the top wall 112 so that the first connection line 130 forms a straight path to the interior volume 118. The skilled artisan will recognize that this is merely one possible configuration, and that the disclosure is not limited to straight connection lines.

A second connection line 140 is positioned between the remote plasma source (RPS) 120 and the interior volume 118 of the chamber body 110. In some embodiments, the second connection line 140 allows a flow of fluid (e.g., gas, liquid, plasma) through the sidewall 114 of the chamber body 110. In some embodiments, the second connection line 140 is configured to allow the flow of fluid through the sidewall 114 to a point below the support surface 125 of the substrate support 124. In some embodiments, the second connection 140 is configured to allow the flow of fluid through the sidewall to a point below the substrate support 124 toward the support shaft 127.

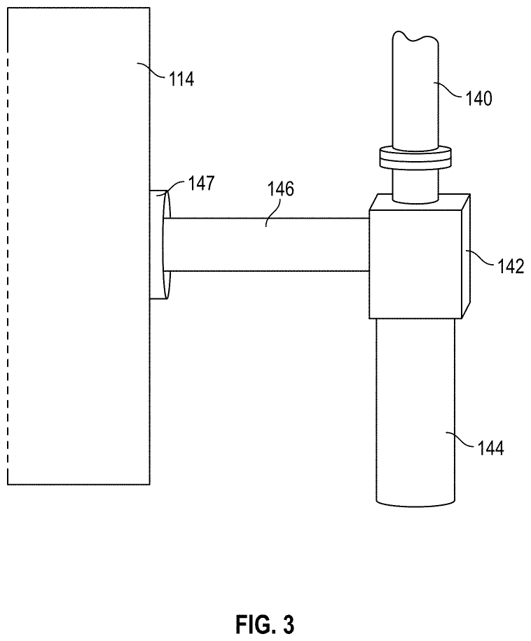

As shown in FIG. 3, in some embodiments, the second connection line 140 comprises a second valve 142. In some embodiments, the second valve 142 is located at the sidewall 114 of the chamber body 110. The second valve 142 can be any suitable valve known to the skilled artisan. In some embodiments, the second valve 142 comprises a manual valve, a pneumatic valve, a solenoid valve, or a hydraulic valve. The illustrated embodiments show a pneumatic second valve 142 with a motor 144 connected to, and configured to, operate the second valve 142.

The second valve 142 isolates the interior volume 118 of the chamber body 110 from the second connection line 140. In some embodiments, the second valve 142 is connected to the chamber sidewall 114 through an extension line 146 attached to the sidewall 114 using a suitable flange 147 or other connection known to the skilled artisan including, but not limited to, a welded connection line extending from the sidewall 114.

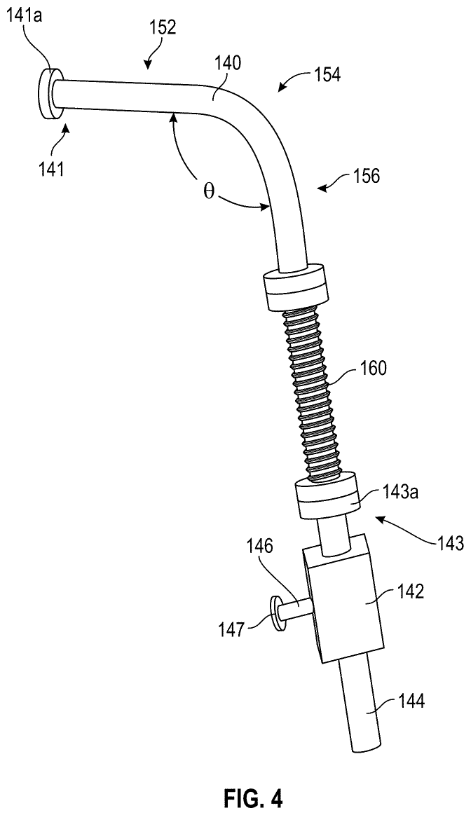

Referring to FIGS. 1, 2 and 4, in some embodiments, the second connection line 140 comprises a first portion 152, a curved portion 154 and a second portion 156. The second connection line 140 has a total length extending from a first end 141 to a second end 143 of the second connection line 140. In the illustrated embodiments, each of the first end 141 and second end 143 has a flange 141a, 143a configured to allow the second connection line 140 to be attached to one or more additional components. For example, the first end flange 141a connects the first end 141 of the second connection line 140 to the first valve 132, and the second end flange 143a connects the second end 143 of the second connection line 140 to an adjacent component. In the embodiment shown, the adjacent component connected to the second end 143 is the second valve 142.

In some embodiments, the first portion 152 of the second connection line 140 is positioned adjacent the top wall 112 of the chamber body 110. In some embodiments, the first portion 152 extends from the first valve 132 toward the sidewall 114 at an angle within ±20° of parallel to the top wall 112. In some embodiments, the first portion 152 of the second connection line 140 has a length less than or equal to 50%, 40%, 30% or 20% of the total length of the second connection line 140.

The second portion 156 of the second connection line 140 is positioned adjacent the sidewall 114 of the chamber body 110. In some embodiments, the second portion 156 extends from the second valve 142 toward the top wall 112 at an angle within ±20° of parallel to the sidewall 114. In some embodiments, the second portion 156 of the second connection line has a length less than or equal to 70%, 60%, 50%, 40%, 30% or 20% of the total length of the second connection line 140.

The curved portion 154 of the second connection line connects the first portion 152 and the second portion 156 to form the overall length of the second connection line 140. The length of the curved portion 154 is any suitable length sufficient to connect the first portion 152 and the second portion 156 to equal the overall length. The curved portion 154 has an angle Θ in the range of 70° to 110°, or in the range of 80° to 100°, or in the range of 85° to 95° or about 90°.

In some embodiments, the second connection line 140 has an overall length in the range of two to six feet. In some embodiments, the second connection line 140 has an overall length less than or equal to seven feet, six feet, five feet, four feet or three feet. In some embodiments, the second portion 156 of the second connection line 140 has a length greater than 6 inches and less than or equal to five feet, four feet or three feet.

In some embodiments, the second portion 156 comprises a bellows 160 to allow the second portion 156 to have a variable length. For example, the bellows 160 may allow the second portion 156 to be stretched between a compressed length and an expanded length, allowing the second connection line 140 to be fit to an existing process chamber.

Referring again to FIGS. 1 and 2, in some embodiments, the first valve 132 comprises a three-way valve. The three-way valve of some embodiments is configured to isolate the remote plasma source (RPS) 120 from the first connection line 130 and the second connection line 140. In some embodiments, the three-way valve has a configuration to allow fluid communication with the interior volume 118 through the first connection line 130. In some embodiments, the three-way valve is configured to allow fluid communication between the remote plasma source (RPS) 120 and the second connection line 140. In some embodiments, the first valve 132 comprises a three-way valve having a first configuration to isolate the RPS 120 from the first connection line 130 and the second connection line 140, a second configuration to allow fluid communication with the interior volume 118 through the first connection line 130, and a third configuration to allow fluid communication between the RPS 120 and the second connection line 140. In some embodiments, the second connection line 140 forms fluid communication between the remote plasma source (RPS) 120 and the interior volume 118 at or below the level of the support surface 125.

Referring to FIG. 1, some embodiments of the disclosure further comprise a controller 190. The controller 190 of some embodiments is connected to the first valve 132 and the second valve 142. In some embodiments, the controller 190 is configured to power and/or control the remote plasma source (RPS) 120. As used in this manner, controlling the remote plasma source means that the controller is able to set one or more of the power, frequency, pressure or gas flow in the RPS. In some embodiments, the controller 190 is configured to control the first valve 132 and control the second valve 142.

The controller 190 may be one of any form of general-purpose computer processor, microcontroller, microprocessor, etc., that can be used in an industrial setting for controlling various chambers and sub-processors. The at least one controller 190 can have a processor, a memory coupled to the processor, input/output devices coupled to the processor, and support circuits to communication between the different electronic components. The memory can include one or more of transitory memory (e.g., random access memory) and non-transitory memory (e.g., storage).

The memory, or computer-readable medium, of the processor may be one or more of readily available memory such as random access memory (RAM), read-only memory (ROM), floppy disk, hard disk, or any other form of digital storage, local or remote. The memory can retain an instruction set that is operable by the processor to control parameters and components of the system. The support circuits are coupled to the processor for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 190 has one or more configurations to execute individual processes or sub-processes to perform the disclosed methods. The controller 190 can be connected to and configured to operate intermediate components to perform the functions of the methods. For example, the controller 190 can be connected to and configured to control one or more of gas valves, actuators, motors, slit valves, vacuum control, etc.

Some embodiments of the disclosure are directed to methods of cleaning a processing chamber. An etching gas (e.g., NF₃ plasma) is flowed through a remote plasma source (RPS) into a chamber interior through a top wall or showerhead to clean the chamber. After stopping the flow of etching gas, with the plasma turned off, a recovery gas (e.g., NH₃) is flowed through the first connection line from the RPS to the interior volume of the chamber. The recovery gas is then directed through a second connection line to enter the chamber interior through the sidewall or bottom wall of the chamber body. After a predetermined amount of time, the recovery gas flow is stopped and the chamber is purged using a suitable inert gas (e.g., N₂).

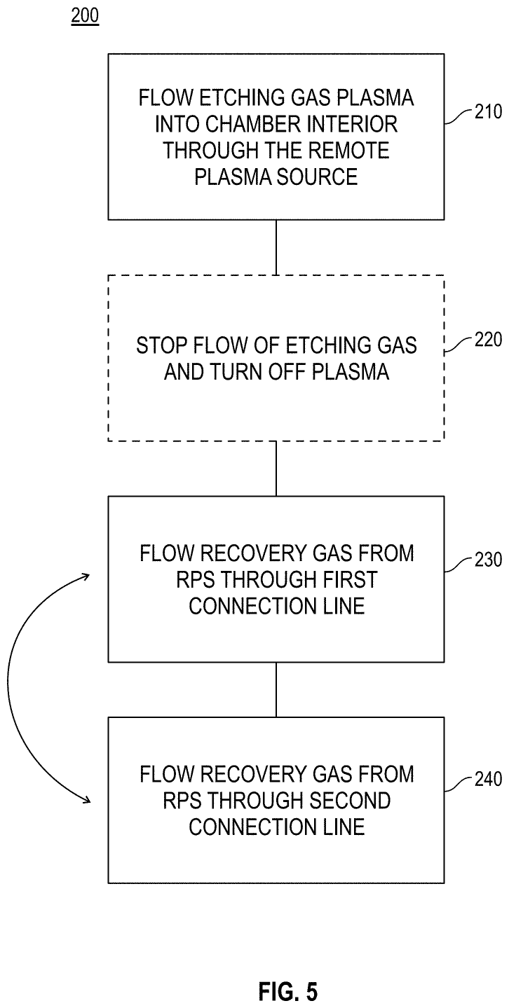

With reference to FIGS. 1, 2 and 5, some embodiments of the disclosure are directed to methods 200 of cleaning a processing chamber 100. At operation 210, an etchant gas is flowed into a remote plasma source (RPS) 120 positioned outside a chamber body 110. A plasma is generated from the etchant gas in the RPS and flowed into the processing chamber 100 interior volume 118 through a first connection line 130. In some embodiments, the plasma generated from the etchant gas in the RPS is flowed into the processing chamber 100 interior volume 118 through the second connection line 140. In some embodiments, the plasma generated from the etchant gas in the RPS is flowed into the processing chamber 100 interior volume 118 through both the first connection line 130 and the second connection line 140 either sequentially or at the same time.

In some embodiments, after a predetermined amount of time, at optional operation 220, the etchant gas flow is stopped, and the plasma is extinguished in the RPS. In some embodiments, the etchant gas flow is replaced with the recovery gas flow without extinguishing the plasma. In some embodiments, the recovery gas is co-flowed with argon, or other suitable gas (e.g., helium, xenon, krypton), which is ignited into a plasma in the RPS 120.

At operation 230, a recovery gas is flowed into the remote plasma source (RPS) 120 and directed to the first connection line into the interior volume 118. At operation 240, the recovery gas is flowed from the RPS 120 through a second connection line 140 into the interior volume 118 of the processing chamber 100 through a sidewall 114 of the chamber body 110. After a predetermined amount of time, the recovery gas flow is stopped, and the chamber is purged with a suitable inert gas. In some embodiments, the recovery gas is flowed through the second connection line at operation 240 before flowing the recovery gas through the first connection line at operation 230, reversing these operations. The recovery gas of some embodiments is flowed through one of the first connection line 130 or the second connection line 140 at a time. In some embodiments, the recovery gas is flowed into the interior volume 118 through the sidewall of the chamber without passing through the second connection line.

In some embodiments, the method 200 further comprises controlling a first valve 132 on the first connection line 130, the first valve comprising a three-way valve having a first configuration to isolate the RPS 120 from the first connection line 130 and the second connection line 140. The three-way valve of some embodiments includes a second configuration to allow fluid communication with the interior volume 118 through the first connection line 130, and a third configuration to allow fluid communication between the RPS 120 and the second connection line 140.

In some embodiments, a second valve 142 on the second connection line 140 is controlled to isolate the interior volume 118 of the chamber body 110 from the second connection line 140.

In some embodiments, the method is operated using controller 190 which has one or more configurations selected from: a configuration to flow an etchant gas into the RPS; a configuration to ignite a plasma in the RPS; a configuration to control the first valve to allow a flow of gas from the RPS through the first connection line 130; and a configuration to control the first valve to allow a flow of gas from the RPS through the second connection line 140; and/or a configuration to control a second valve 142 to isolate the second connection line 140 from the interior volume 118 of the chamber body 110.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

1. A processing chamber comprising:
a chamber body comprising a top wall, a sidewall and a bottom wall defining an interior volume;
a remote plasma source (RPS) outside the chamber body;
a first connection line between the remote plasma source (RPS) and the interior volume through the top wall; and
a second connection line between the remote plasma source (RPS) and the interior volume through the sidewall.

2. The processing chamber of claim 1, wherein the first connection line comprises a first valve to isolate the RPS from the first connection line.

3. The processing chamber of claim 2, wherein the first valve comprises a manual valve, a pneumatic valve, a solenoid valve, or a hydraulic valve.

4. The processing chamber of claim 2, wherein the first valve comprises a three-way valve having a first configuration to isolate the RPS from the first connection line and the second connection line, a second configuration to allow fluid communication with the interior volume through the first connection line, and a third configuration to allow fluid communication between the RPS and the second connection line.

5. The processing chamber of claim 4, wherein the second connection line comprises a second valve at the sidewall to isolate the interior volume from the second connection line.

6. The processing chamber of claim 5, wherein the second valve comprises a manual valve, a pneumatic valve, a solenoid valve, or a hydraulic valve.

7. The processing chamber of claim 1, wherein the RPS is positioned above the top wall so that the first connection line forms a straight path to the interior volume.

8. The processing chamber of claim 7, wherein the second connection line comprises a first portion adjacent the top wall, a second portion adjacent the sidewall and a curved portion connecting the first portion to the second portion.

9. The processing chamber of claim 8, wherein the second portion comprises a bellows to allow the second portion to have a variable length.

10. The processing chamber of claim 8, wherein the second connection line has a length in a range of two to six feet.

11. The processing chamber of claim 1, further comprising a showerhead within the interior volume adjacent the top wall and a substrate support having a support surface within the interior volume spaced a distance from the showerhead.

12. The processing chamber of claim 11, wherein the first connection line forms fluid communication between the RPS and the showerhead.

13. The processing chamber of claim 11, wherein the second connection line forms fluid communication between the RPS and the interior volume at or below a level of the support surface.

14. The processing chamber of claim 5, further comprising a controller connected to the first valve and the second valve, the controller configured to power the RPS, provide a flow of recovery gas through the RPS, control the first valve and control the second valve.

15. A method of cleaning a processing chamber, the method comprising:
flowing a recovery gas into a remote plasma source (RPS) positioned outside a chamber body comprising a top wall, a sidewall and a bottom wall defining an interior volume;
flowing the recovery gas through a second connection line from the RPS to the interior volume through the sidewall of the chamber body; and
flowing the recovery gas through a first connection line from the RPS to the interior volume through the top wall of the chamber body.

16. The method of claim 15, wherein the recovery gas is flowed through one of the first connection line or the second connection line at a time.

17. The method of claim 16, further comprising controlling a first valve on the first connection line, the first valve comprising a three-way valve having a first configuration to isolate the RPS from the first connection line and the second connection line, a second configuration to allow fluid communication with the interior volume through the first connection line, and a third configuration to allow fluid communication between the RPS and the second connection line.

18. The method of claim 17, wherein the first valve is a manual valve, a pneumatic valve, a solenoid valve, or a hydraulic valve.

19. The method of claim 17, further comprising controlling a second valve at the sidewall of the chamber body to isolate the interior volume from the second connection line.

20. The method of claim 19, wherein the second valve comprises a manual valve, a pneumatic valve, a solenoid valve, or a hydraulic valve.
